(19) United States
(12) Patent Application Publication
(10) Pub. No.: US 2022/0356577 A1
(43) Pub. Date: Nov. 10, 2022

(54) SUBSTRATE PROCESSING APPARATUS AND METHOD

(71) Applicant: Picosun Oy, Espoo (FI)

(72) Inventors: Väinö KILPI, Masala (FI); Tom BLOMBERG, Masala (FI)

(73) Assignee: Picosun Oy, Espoo (FI)

(21) Appl. No.: 17/735,736

(22) Filed: May 3, 2022

(30) Foreign Application Priority Data
May 10, 2021 (FI) 20215554

(51) Int. Cl. C23C 16/455; C23C 16/56

(52) U.S. Cl. CPC C23C 16/45544; C23C 16/56

(57) ABSTRACT

A substrate processing apparatus, includes a reaction chamber, an outer chamber at least partly surrounding the reaction chamber wherein an intermediate space is formed between the reaction chamber and the outer chamber, at least one heater element, at least one heat distributor in the intermediate space, and at least one heater element feedthrough in the outer chamber allowing at least a part of the at least one heater element to pass through into the intermediate space and to couple with the at least one heat distributor.

### FIELD OF THE INVENTION

The present invention generally relates to substrate processing apparatus and a method. More particularly, but not exclusively, the invention relates to chemical deposition or etching reactors.

### BACKGROUND OF THE INVENTION

This section illustrates useful background information without admission of any technique described herein representative of the state of the art.

In chemical deposition methods, such as atomic layer deposition (ALD) or atomic layer etching (ALE), the required temperature for surface reactions is obtained through heating. The heating is often achieved by applying heaters positioned in, or outside the walls of the reaction chamber of the substrate processing apparatus. Regardless of the material used to act as a heat source, the heater surface is commonly known to suffer from oxidation and subsequently corrosion may occur due to certain chemicals leaking from the reaction chamber of the apparatus. As the heaters are generally fixed in the structure of the apparatus, it can be laborious to remove them, for instance when trying to exchange the heaters or access other parts of the apparatus. Therefore, there is an ongoing need to develop improved heater solutions which are easily removable, or at least to provide alternatives to existing solutions.

### SUMMARY

It is an object of certain embodiments of the invention to provide an improved substrate processing apparatus or at least to provide an alternative solution to existing technology.

According to a first example aspect of the invention there is provided a substrate processing apparatus, comprising:

a reaction chamber;

an outer chamber at least partly surrounding the reaction chamber, wherein an intermediate space is formed between the reaction chamber and the outer chamber;

at least one heater element;

at least one heat distributor in the intermediate space; and

at least one heater element feedthrough in the outer chamber allowing at least a part of the at least one heater element to pass through into the intermediate space and to couple with the at least one heat distributor.

In certain embodiments, the at least one heater element is a cartridge heater, which is removable and exchangeable.

In certain embodiments, the at least one heater element is configured to be removably coupled with the at least one heat distributor. In certain embodiments, the at least one heater element is configured to be reversibly placed, at least partly inside the at least one heat distributor. In certain embodiments, with a removably placed heater element is meant a reversibly placed heater element, meaning that the heater element can be removed from its position the same way it was placed in the said position in the first place. In certain embodiments, with the at least one heater element being coupled with the at least one heat distributor is meant, that the at least one heater element is in thermal contact with the at least one heat distributor.

In certain embodiments, the at least one heater element is configured to be removably and/or reversibly placed, at least partly, inside two separate heat distributors.

In certain embodiments, the heater element is an elongated element. In certain embodiments, the at least one heater element is vertically oriented along its elongated shaft, when placed in its operational position. In certain other embodiments, the at least one heater element is oriented horizontally or diagonally along its elongated shaft when placed in its operational position. In certain embodiments, the heater element is positioned in its operational position below the reaction chamber. In certain embodiments, the heater element is positioned in its operational position on top of the reaction chamber. In certain embodiments, the heater element is positioned in its operational position at a side of the reaction chamber.

In certain embodiments, the apparatus comprises more than one heater element. In certain embodiments the apparatus comprises at least two, at least three or at least four heater elements. In certain embodiments, the apparatus comprises more than four heater elements.

In certain embodiments, the at least one heater element is an elongated rod-shaped element. In certain embodiments, the heater element is rotationally symmetric from its horizontal cross section, when oriented vertically along its elongated shaft. In certain embodiments, when oriented vertically along its elongated shaft, the heater element is flattened from its vertical sides facing the reaction chamber and outer chamber.

In certain embodiments, the maximum voltage applied to the heater element depends on the shape and size of the heater element. In an embodiment, the voltage applied is 48-240 V. In certain embodiments, the maximum heating power is dependent on the voltage and the amount of heating wire arranged inside the heating element.

In certain embodiments, the maximum heating power and voltage applied to the heater element depends on the type of the heater element. For example, the heater element can be a radiant heater, a conduction heater or a convection heater, if applicable.

In certain embodiments, the at least one heater element is configured to be removably placed, at least partly, in the intermediate space between the outer chamber and the reaction chamber, through the heater element feedthrough in the outer chamber. In certain embodiments, the at least one heater element feedthrough is in a bottom of the outer chamber. In certain embodiments, the at least one heater element feedthrough is in a top of the outer chamber. In certain embodiments, the at least one heater element feedthrough is in a side of the outer chamber. In certain embodiments, the at least one heater element feedthrough is tightened or sealed from the outside of the outer chamber, for sealing the heater element entrance. In certain embodiments, each heater element feedthrough in the outer chamber comprises a seal between the heater element feedthrough and the heater element. In certain embodiments, the said seal is arranged outside the outer chamber, for sealing the heater element entrance. In certain embodiments, the said seal is arranged inside the heater element feedthrough, for sealing the heater element entrance. In certain embodiments, the seal is a flange, for example a vacuum flange. In certain embodiments, the seal is a cover plate. In certain embodiments, the seal comprises an o-ring.

In certain embodiments, the apparatus comprises a plurality of heat distributors, the plurality of heat distributors surrounding at least partly the periphery of the reaction chamber. In certain embodiments, a plurality of heat distributors means two or more heat distributors. In certain embodiments, the apparatus comprises more than one heat distributor. In certain embodiments the apparatus comprises at least two, at least three or at least four heat distributors. In certain embodiments, the apparatus comprises four quarter circle heat distributors.

In certain embodiments, the at least one heat distributor is configured to distribute thermal radiation, convection or conduction, if applicable, effectively and evenly to the periphery of the reaction chamber. In certain embodiments, the heat distributor is configured to distribute thermal radiation, convection or conduction, if applicable, effectively and evenly into and through the reaction chamber wall.

In certain embodiments, the at least one heat distributor is configured to heat the reaction chamber to a uniform temperature. In certain embodiments, the at least one heat distributor is configured to convey heat uniformly to the inner volume of the reaction chamber and to at least one substrate in the reaction chamber.

In certain embodiments, the at least one heat distributor is a panel-like element and/or a curved structure. In certain embodiments, the heat distributor is a curved panel-like element. In certain embodiments, the apparatus comprises four quarter circle heat distributors and one heater element coupled with each of the four heat distributors. In certain embodiments, the apparatus comprises four quarter circle heat distributors and four heater elements, each heater element being coupled with two of the said four heat distributors.

In certain embodiments, the apparatus comprises one heat distributor. In certain embodiments, the one heat distributor is formed of a single part. In certain embodiments, the one heat distributor is shaped as a hollow curved or circular cylinder or a tube.

In certain embodiments, each heat distributor is heated by at least one heater element. In certain embodiments, each heat distributor is heated by two heater elements. In certain embodiments, each heat distributor is heated by a plurality of heater elements.

In certain embodiments, the material of the heat distributor is aluminum. In certain other embodiments, the material of the heat distributor is selected from copper, brass, titanium, steel, ceramic, or silicon nitride.

In certain embodiments, the intermediate space is configured to maintain vacuum conditions. In certain embodiments, the apparatus is configured to maintain the pressure in the intermediate space, wherein the at least one heat distributor is positioned in, at 100-0,01 mbar. In certain embodiments, the apparatus is configured to maintain the pressure in the intermediate space at 10-0,1 mbar or at 5-0,1 mbar during the process cycle of deposition or etching. In certain embodiments, the pressure in the intermediate space is kept at 100-0,01 mbar, more preferably at 10-0,1 mbar or at 5-0,1 mbar also during a time period that follows (or is subsequent to) the process cycle.

In certain embodiments, the apparatus comprises a sheath element between the at least one heater element and the at least one heat distributor, to protect the at least one heater element. In certain embodiments, the sheath element between the heater element and the heat distributor is configured to convey heat from the at least one heater element to the at least one heat distributor. In certain embodiments, the sheath element between the heater element and the heat distributor is configured to conduct heat from the at least one heater element to the at least one heat distributor. In certain embodiments, the at least one heater element is coupled with the at least one heat distributor via the sheath element. In certain embodiments, the sheath element in its operational position is configured to be in contact with the at least one heat distributor. In certain embodiments, the sheath element in its operational position is configured to be in contact with the at least one heater element. In certain embodiments, the sheath element is configured to serve as a housing for the at least one heater element when inserted, at least partly, in its operational position. In certain embodiments, the sheath element is configured to cover the entire heater element surface within the intermediate space, to protect the heater element. In certain embodiments, the sheath element is configured to cover most of the heater element surface within the intermediate space.

In certain embodiments, the sheath element is vertically oriented along its elongated shaft, when placed in its operational position around the heater element. In certain other embodiments, the sheath element is oriented horizontally or diagonally along its elongated shaft, when placed in its operational position around the heater element.

In certain embodiments, the sheath element comprises a surface structure which supports the at least one heat distributor. In certain embodiments, the sheath element comprises a surface structure which supports the weight of the at least one heat distributor.

In certain embodiments, the at least one heater element is configured to be removably placed, at least partly, inside the sheath element. In certain embodiments, the at least one heater element is configured to be reversibly placed, at least partly, inside the sheath element. In certain embodiments, the at least one heater element is configured to be at least partly placed inside an inner cavity of the sheath element.

In certain embodiments, the sheath element is an elongated sleeve-like element. In certain embodiments, both distal tips of the elongated shaft of the sheath element are open-ended. In certain embodiments, one distal tip of the elongated shaft of the sheath element is closed or has a blind end. In certain embodiments, the material of the sheath element is aluminum. In certain other embodiments, the material of the sheath element is selected from the group comprising stainless steel, copper and molybdenum, or similar metals with a good thermal conductivity.

In certain embodiments, each heater element is covered by the sheath element inside the intermediate space beyond the point where it penetrates the heater element feedthrough. In certain embodiments, the sheath element is coupled with the seal between the heater element feedthrough and the heater element. In certain embodiments, the sheath element is coupled with the vacuum flange in the heater element feedthrough. In certain embodiments, the sheath element is configured to protect the heater element in the intermediate space. In certain embodiments, the sheath element is configured to support and fix the position of the heat distributor in the vertical direction. In certain embodiments, the sheath element is configured to support and fix the position of the heat distributor also in the horizontal direction.

In certain embodiments, the at least one heat distributor comprises at least one opening or a hole, to insert the at least one heater element at least partly inside the heat distributor. In certain embodiments, one heat distributor comprises a plurality of openings or holes, to insert a plurality of heater elements at least partly inside the one heat distributor. In certain embodiments, the at least one opening or hole is configured to have both, the heater element and the sheath element, at least partly, inserted inside the said opening or hole. In certain embodiments, the said at least one opening or hole is configured to pierce one narrow edge of the heat distributor. In certain embodiments, the said at least one opening or hole in one of the narrow edges of the heat distributor is configured to penetrate through the entire heat distributor, the said opening or hole piercing two narrow edges of the heat distributor. In certain embodiments, with a narrow edge of the heat distributor is meant a narrow edge which is not a flat, panel-like surface of the heat distributor.

In certain embodiments, any two adjacent heat distributors are coupled and/or in thermal contact with each other through their adjacent narrow edges being in surface-to-surface contact with each other.

In certain embodiments, any two adjacent heat distributors have at least one bushing or a duct, comprising the said opening or hole, in at least one, preferably in two of their narrow edges. In certain embodiments, any two adjacent heat distributors have the at least one bushing or a duct at different vertical height from each other, allowing an overlay between the adjacent bushings or ducts, and thereby allowing an overlay between the adjacent heat distributors. In certain embodiments, any two adjacent heat distributors are coupled with the at least one heater element inserted inside the overlaid bushings or ducts of the two adjacent heat distributors. In certain embodiments, any two adjacent heat distributors are coupled with a sheath element inserted inside the overlaid bushings or ducts of the two adjacent heat distributors, and one heater element inserted inside the said sheath element.

In certain other embodiments, the at least one heat distributor comprises at least one fastening, to attach the heater element to the heat distributor. In certain embodiments, one heat distributor comprises a plurality of fastenings, to attach a plurality of heater elements to the one heat distributor. In certain embodiments, the at least one fastening is configured to attach both, the heater element, and the sheath element, to the heat distributor.

In certain embodiments, the at least one heater element, in its operational position, is placed at least partly inside each of

the intermediate space;

the sheath element;

the at least one heat distributor; and

the heater element feedthrough.

In certain embodiments, the at last one heat distributor is positioned in the intermediate space a distance apart from the reaction chamber. In certain embodiments, the at last one heat distributor in the intermediate space is in contact with or connected to the reaction chamber wall directly. In certain embodiments, the at last one heat distributor is positioned beside the reaction chamber to cover at least partly the periphery of the reaction chamber. In certain embodiments, the at last one heat distributor is positioned substantially vertically along its flat, panel-like surface beside the reaction chamber. In certain embodiments, the at last one heat distributor is positioned below the reaction chamber to at least partly cover the bottom or the lower part of the reaction chamber. In certain embodiments, the at last one heat distributor is positioned substantially horizontally along its flat, panel-like surface below the reaction chamber. In certain embodiments, the at last one heat distributor is positioned above the reaction chamber to at least partly cover the top or the upper part of the reaction chamber. In certain embodiments, the at last one heat distributor is positioned substantially horizontally along its flat, panel-like surface above the reaction chamber.

In certain embodiments, thermal energy is conducted to the heat distributor(s) located below or above the reaction chamber from the heat distributors at the side of the reaction chamber. In certain embodiments, thermal energy is conducted to the heat distributor(s) located below or above the reaction chamber from the heater element(s) coupled with or placed in contact with the said heat distributor(s). In certain embodiments, the at last one heat distributor is positioned at the side of the reaction chamber to cover most of, or the entire periphery of the reaction chamber. In such embodiments, the at least one heater element feedthrough, through which the at least one heater element is inserted, is in the bottom or in the top of the outer chamber. In certain embodiments, the at least one heat distributor is positioned above and/or below the reaction chamber to cover the top and/or the bottom of the reaction chamber. In such embodiments, the at least one heater element feedthrough, through which the at least one heater element is inserted, is in the side of the outer chamber.

In certain embodiments, the apparatus comprises at least one substantially horizontal reflection plate, below the reaction chamber in the intermediate space, covering at least part of the bottom of the reaction chamber. In certain embodiments, the apparatus comprises at least one substantially horizontal reflection plate above the reaction chamber in the intermediate space, covering at least part of the top of the reaction chamber. The at least one substantially horizontal reflection plate is configured to reflect thermal radiation, convection or conduction, if applicable, towards the reaction chamber. In certain embodiments, the apparatus comprises a plurality of overlaid substantially horizontal reflection plates below or above the reaction chamber, to form a plurality of substantially horizontal reflection plate layers. In certain embodiments, one substantially horizontal reflection plate layer comprises or consists of a plurality of individual substantially horizontally oriented reflection plate units. In certain embodiments, all the substantially horizontal reflection plates, are positioned in the intermediate space, between the reaction chamber and the outer chamber.

In certain embodiments, the apparatus comprises at least one substantially vertically oriented reflection plate, at least partly surrounding the reaction chamber. In certain embodiments, the apparatus comprises a plurality of substantially vertically oriented reflection plates, at least partly surrounding the reaction chamber. In certain embodiments, the plurality of substantially vertically oriented reflection plates are overlaid on top of each other, to form a plurality of substantially vertical reflection plate layers. In certain embodiments, one substantially vertical reflection plate layer comprises or consist of a plurality of individual substantially vertically oriented reflection plate units. In certain embodiments, all the substantially vertically oriented reflection plates are positioned in the intermediate space, between the reaction chamber and the outer chamber.

In certain embodiments, the reflection plates are configured to reflect heat back towards the heated parts of the reaction chamber, and to prevent heat affecting other components of the apparatus located outside the volume bordered by the reflection plates.

In certain embodiments, the at least one heater element is inserted through an opening or a hole in the at least one substantially horizontal reflection plate. In certain embodiments, the at least one heater element is inserted through openings or holes in a plurality of substantially horizontal reflection plates layered on top of each other. In certain embodiments, the heater element is covered by the sheath element inside the intermediate space beyond the point where it penetrates the at least one substantially horizontal reflection plate. In certain embodiments, the at least one heater element is inserted through an opening or a hole in the at least one substantially vertical reflection plate. In certain embodiments, the at least one heater element is inserted through openings or holes in a plurality of substantially vertical reflection plates layered on top of each other. In certain embodiments, the heater element is covered by the sheath element inside the intermediate space beyond the point where it penetrates the at least one substantially vertical reflection plate.

In certain embodiments, the at least one heater element is configured to heat all the heat distributors simultaneously residing in the intermediate space to a temperature of at least 30° C. In certain embodiments, all the heater elements simultaneously residing in the intermediate space, are configured to heat together all the heat distributors simultaneously residing in the intermediate space to a temperature of at least 30° C. In certain embodiments, all the heater elements simultaneously residing in the intermediate space, together with any other optional heaters, are configured to heat the reaction chamber comprising the inner volume of the reaction chamber to a temperature of at least 30° C., at least 80° C., at least 120° C., or at least 200° C., or at least 500° C. In an embodiment, all the heater elements simultaneously residing in the intermediate space, together with any other optional heaters, are configured to heat the reaction chamber comprising the inner volume of the reaction chamber to a temperature of 150° C.-300° C.

In certain embodiments the type of the heater element can be exchanged according to the need of a specific type of a heater. In certain embodiments, the heater element is a radiant heater. In certain embodiments, the heater element is a convection heater. In certain embodiments, the heater element is a conduction heater. In certain embodiments, the heater element is an infrared (IR) heater.

In certain embodiments, the at least one heat distributor has a surface structure which optimizes the heat emission towards the reaction chamber.

In certain embodiments, the at least one heat distributor has a different surface structure on the side that is facing the reaction chamber, than on the side that is facing the outer chamber, to optimize the desired heat emission and thermal radiation and/or convection and/or conduction, if applicable.

In certain embodiments, the surface of the heat distributor facing the reaction chamber is uneven, rough, or coarse. In certain embodiments, the surface of the heat distributor facing the reaction chamber has a good thermal emissivity. In certain embodiments, the surface of the heat distributor facing the reaction chamber is coated with a material with a good thermal emissivity. In certain embodiments, the thickness of the coating on the heat distributor surface facing the reaction chamber is optimized for maximal thermal emission. In certain embodiments, the surface of the heat distributor facing the outer chamber is smooth, even, polished, or unwrinkled. In certain embodiments, the surface of the heat distributor facing the outer chamber has a low thermal emissivity. In certain embodiments, the surface of the heat distributor facing the outer chamber is coated with a material that has a low thermal emissivity. In certain embodiments, the thickness of the coating on the heat distributor surface facing the outer chamber is optimized for minimal thermal emission.

In certain embodiments, the at least one substantially vertically oriented reflection plate has a material and a surface structure which optimizes the reflection of the thermal radiation, convection or conduction, if applicable, towards the reaction chamber. In certain embodiments, the at least one substantially horizontally oriented reflection plate has a material and a surface structure which optimizes the reflection of the thermal radiation, convection or conduction, if applicable, towards the reaction chamber.

According to a second example aspect of the invention there is provided a method, comprising:

providing an outer chamber at least partly surrounding a reaction chamber of a substrate processing apparatus, wherein an intermediate space is formed between the reaction chamber and the outer chamber;

passing at least a part of at least one heater element into the intermediate space through a heater element feedthrough in the outer chamber; and

coupling at least one heat distributor in the intermediate space with the at least one heater element.

In certain embodiments, the method comprises removably coupling the at least one heater element with the at least one heat distributor.

In certain embodiments, the method comprises removably placing the at least one heater element at least partly in the intermediate space between the outer chamber and the reaction chamber, through the heater element feedthrough in the outer chamber.

In certain embodiments, the method comprises heating the reaction chamber to a uniform temperature with heat distributed by the at least one heat distributor.

In certain embodiments, the substrate processing method comprises processing the at least one substrate with metal oxide in the reaction chamber by atomic layer deposition (ALD) and selecting the thickness of the atomic layer deposition on the at least one substrate. In certain embodiments, the metal oxide is selected from Al₂O₃, Si₃N₄ and SiO₂; and the thickness of the selected deposition on the at least one substrate is between 5-15 nm, preferably the thickness is 10 nm.

Different non-binding example aspects and embodiments have been illustrated in the foregoing. The above embodiments are used merely to explain selected aspects or steps that may be utilized in implementations of the present invention. Some embodiments may be presented only with reference to certain example aspects. It should be appreciated that corresponding embodiments apply to other example aspects as well. In particular, the embodiments described in the context of the first aspect are applicable to each further aspect. Any appropriate combinations of the embodiments may be formed.

### BRIEF DESCRIPTION OF THE DRAWINGS

The invention will now be described, by way of example only, with reference to the accompanying drawings, in which:

FIG. 1 shows a schematic cross section of certain parts of a substrate processing apparatus in accordance with certain embodiments;

FIG. 2 shows a perspective view of certain parts of the apparatus in accordance with certain embodiments; and

FIG. 3 shows two alternative perspective views of certain parts of the apparatus in accordance with certain embodiments;

FIG. 4 shows a more detailed schematic cross section of certain parts of the substrate processing apparatus in accordance with certain embodiments; and

FIG. 5 shows an alternative detailed schematic cross section of certain parts of the substrate processing apparatus in accordance with certain embodiments.

### DETAILED DESCRIPTION

In the following description, Atomic Layer Deposition (ALD) technology and Atomic Layer Etching (ALE) technology are used as an example.

The basics of an ALD growth mechanism are known to a skilled person. ALD is a special chemical deposition method based on sequential introduction of at least two reactive precursor species to at least one substrate. A basic ALD deposition cycle consists of four sequential steps: pulse A, purge A, pulse B and purge B. Pulse A consists of a first precursor vapor and pulse B of another precursor vapor. Inactive gas and a vacuum pump are typically used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness. Deposition cycles can also be either simpler or more complex. For example, the cycles can include three or more reactant vapor pulses separated by purging steps, or certain purge steps can be omitted. Or, as for plasma-assisted ALD, for example PEALD (plasma-enhanced atomic layer deposition), or for photon-assisted ALD one or more of the deposition steps can be assisted by providing required additional energy for surface reactions through plasma or photon in-feed, respectively. One of the reactive precursors can be substituted by energy (such as mere photons), leading to single precursor ALD processes. Accordingly, the pulse and purge sequence may be different depending on each particular case. The deposition cycles form a timed deposition sequence that is controlled by a logic unit or a microprocessor. Thin films grown by ALD are dense, pinhole free and have uniform thickness.

As for substrate processing steps, the at least one substrate is typically exposed to temporally separated precursor pulses in a reaction vessel (or chamber) to deposit material on the substrate surfaces by sequential self-saturating surface reactions. In the context of this application, the term ALD comprises all applicable ALD based techniques and any equivalent or closely related technologies, such as, for example the following ALD sub-types: MLD (Molecular Layer Deposition), plasma-assisted ALD, for example PEALD (Plasma Enhanced Atomic Layer Deposition) and photon-assisted or photon-enhanced Atomic Layer Deposition (known also as flash enhanced ALD or photo-ALD).

However, the invention is not limited to ALD technology, but it can be exploited in a wide variety of substrate processing apparatuses, for example, in chemical deposition reactors such as Chemical Vapor Deposition (CVD) reactors, or in chemical etching reactors, such as in Atomic Layer Etching (ALE) reactors.

The basics of an ALE etching mechanism are known to a skilled person. ALE is a technique in which material layers are removed from a surface using sequential reaction steps that are self-limiting. A typical ALE etching cycle comprises a modification step to form a reactive layer, and a removal step to take off only the reactive layer. The removal step may comprise using a plasma species, ions in particular, for the layer removal. In context of ALD and ALE techniques, the self-saturating surface reaction means that the surface reactions on the reactive layer of the surface will stop and self-saturate when the surface reactive sites are entirely depleted.

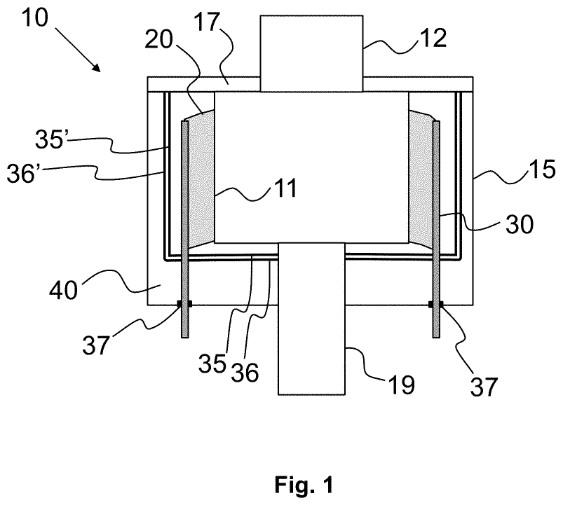

FIG. 1 shows a schematic cross section of certain parts of a substrate processing apparatus 10 in accordance with certain embodiments. The apparatus 10 is a substrate processing apparatus or a reactor which is suitable, for instance, to perform plasma-enhanced ALD and/or UV-ALD deposition reactions and/or ALE etching reactions. In certain embodiments, the apparatus 10 comprises a reaction chamber 11, wherein the processing of at least one substrate takes place. An outer chamber 15 is arranged, at least partly, around the reaction chamber 11. In certain embodiments the outer chamber 15 encloses the entire reaction chamber 11 within, whereas in some other embodiments, only a certain part of the reaction chamber 11 is enclosed inside the outer chamber 15. An intermediate space 40 is delimited between the walls of the outer chamber 15 and the reaction chamber 11. In certain embodiments, the outer chamber 15 is configured to enclose a specific atmosphere and pressure conditions within the intermediate space 40, which conditions are different from the conditions inside the reaction chamber and in the space surrounding the outer chamber 15 from the outside. For example, the atmosphere and pressure conditions of the intermediate space 40 are adopted not to affect the reaction inside the reaction chamber 11, should a leak into the reaction chamber 11 occur. In an embodiment, the atmosphere of the intermediate space 40 comprises an inert gas, such as N₂ or Ar, for example. In certain embodiments, on top of the outer chamber 15 and the reaction chamber 11 is a lid structure 17, which is openable. In certain embodiments, the lid structure 17 comprises both a lid for the outer chamber 15 and a lid for the reaction chamber 11. Accordingly, the intermediate space 40 and the inner volume of the reaction chamber 11 can be accessed through the openable lid structure 17. In certain other embodiments, the lid structure 17 comprises only a lid for the outer chamber 15, and the reaction chamber 11 comprises a separate lid structure (not shown). In certain embodiments, the apparatus 10 comprises a reactant inlet part 12, configured to provide the reaction chamber 11 with reactant(s) and/or additional energy. The reactant inlet part 12 is provided on the top side of the reaction chamber 11, in connection to the lid structure 17. In certain embodiments, the reactant inlet part 12 comprises an energy source, such as a plasma source or a radiation source.

In certain embodiments the apparatus 10 comprises at least one substantially horizontal reflection plate 35, 36, located in the intermediate space 40 between the reaction chamber 11, and the outer chamber 15. In certain embodiments the apparatus 10 comprises more than one substantially horizontal reflection plate 35, 36, located in the intermediate space 40 between the reaction chamber 11, and the outer chamber 15. The reaction chamber 11 is supported by a base 19, wherein the base 19 comprises the reaction chamber 11 exhaust outlet (not shown). The base 19 extends through the at least one substantially horizontal reflection plate 35, 36, located in the intermediate space 40 between the reaction chamber 11, and the outer chamber 15. In certain embodiments, the base 19 extends from the reaction chamber 11 bottom downwards through the outer chamber 15. In certain embodiments, the apparatus 10 comprises more than one overlaid substantially horizontal reflection plate 35, 36 layered below the reaction chamber 11, in which case the base 19 extends through these overlaid substantially horizontal reflection plates 35, 36. In certain embodiments, the apparatus 10 comprises more than one overlaid substantially horizontal reflection plate 35, 36 layered above the reaction chamber 11. In certain embodiments the apparatus 10 comprises at least one substantially vertically oriented reflection plate 35′, 36′ in the intermediate space 40 between the reaction chamber 11 and the outer chamber 15. In certain embodiments, the apparatus comprises more than one substantially vertically layered reflection plate 35′, 36′ in the intermediate space 40 between the reaction chamber 11 and the outer chamber 15. In certain embodiments, the apparatus 10 comprises at least one substantially horizontal reflection plate 35, 36 in the intermediate space 40 between the reaction chamber 11 and the outer chamber 15, and at least one substantially vertically oriented reflection plate 35′, 36′, in the intermediate space 40 between the reaction chamber 11 and the outer chamber 15. In other embodiments, the apparatus 10 comprises more than one substantially horizontal reflection plate 35, 36 layered in the intermediate space 40 between the reaction chamber 11 and the outer chamber 15, and more than one substantially vertically oriented reflection plate 35′, 36′, layered in the intermediate space 40 between the reaction chamber 11 and the outer chamber 15. In certain embodiments, the apparatus 10 comprises at least one curved or bent reflection plate 35, 36, 35′, 36′ in the intermediate space 40, between the reaction chamber 11 and the outer chamber 15, surrounding the reaction chamber 11 at least partly. In certain embodiments, the apparatus 10 comprises more than one curved or bent reflection plate 35, 36, 35′, 36′ in the intermediate space 40, between the reaction chamber 11 and the outer chamber 15, surrounding the reaction chamber 11 at least partly.

The reflection plates 35, 36, 35′, 36′ are configured to reflect thermal radiation, convection or conduction, if applicable, emitted by the at least one heater element 30 and the at least one heat distributor 20 towards the reaction chamber 11, and away from the outer chamber 15 as well as the other parts of the apparatus located behind the periphery of the reflection plates 35, 36, 35′, 36′. Each of the individual reflection plates 35, 36, 35′, 36′ can comprise or consist of a plurality of individual reflection plate units, the units forming one layer of a reflection plate oriented either substantially horizontally or vertically, or both. The apparatus may also comprise other reflection plates on top of the said reflection plates 35, 36, 35′, 36′ (not shown).

The apparatus 10 comprises at least one heater element 30, to provide heat inside the apparatus 10. The at least one heater element 30 can be, for example, a cartridge heater, configured to be placed in the correct position inside the apparatus 10, and to be removed and exchanged removably and/or reversibly. The cartridge heater can be a tube-shaped heater element, which can be custom manufactured to a specific watt density, based on its intended application. For example, certain cartridge heater designs can reach a watt density of up to 50 W/cm² while some other designs can reach a watt density of up to 100 W/cm². Exchangeability of the heater element 30 is useful in case the heater element needs to be replaced to a new one, for example, due to heater element surface oxidation. In certain embodiments, the apparatus 10 comprises more than one heater element 30, the number of heater elements 30 being adjusted to provide adequate heating for the surface reactions inside the reaction chamber 11, depending on the individual design of the apparatus 10. The at least one heater element 30 is preferably a rod-shaped element. Its horizontal cross section can be rotationally symmetric or round when the heater element is positioned vertically along its elongated axis. In certain other embodiments, the horizontal cross section of the heater element 30 can also be rotationally asymmetric, such as oval, rectangle, or square, when the heater element is positioned vertically along its elongated axis. Nonetheless, the at least one heater element 30 is a slim rod-, or cane-shaped object, and the thickness and shape of the heater element 30 are optimized for aspects such as usability, carrying capacity and user safety.

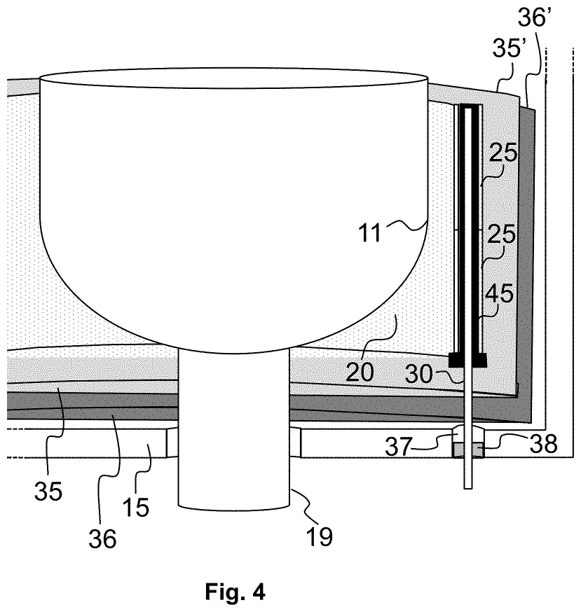

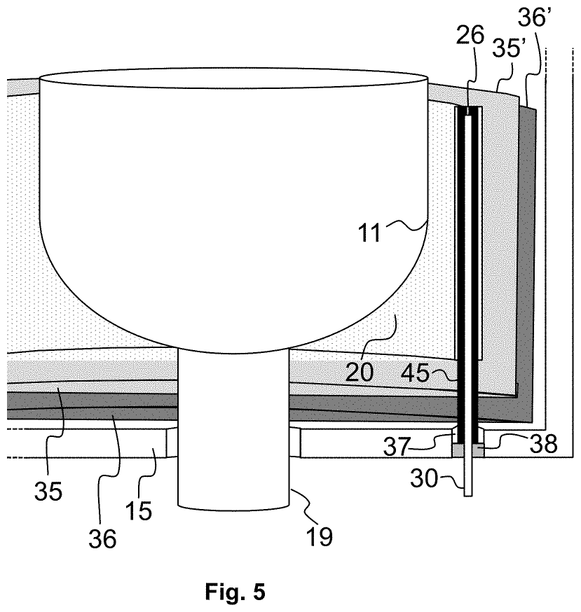

The at least one heater element 30 is positioned in its operational position, at least partly inside the intermediate space 40 formed between the reaction chamber 11 and the outer chamber 15. By the operational position of the at least one heater element 30 is meant a position, wherein the heater element 30 can be operated or is operational in a substrate processing apparatus 10, i.e., it can convey heat according to its intended purpose. While being positioned in its operational position, part of the heater element 30 can be located outside the outer chamber 15. Each individual heater element 30 is inserted to its operational position in the intermediate space 40 through its respective heater element feedthrough 37, located in the bottom of the outer chamber 15. However, in some alternative embodiments, the heater element feedthrough(s) 37, can also be located in the side of the outer chamber 15, or in the top part of the outer chamber 15. In certain embodiments, the at least one heater element feedthrough 37 is configured to provide support and fix the position of the heater element(s) 30 and/or the heat distributor(s) 20. The heater element feedthrough 37 is preferably tightened with a seal 38 as indicated in the FIGS. 4 and 5, while the heater element 30 is positioned in its operational position, to prevent ambient pressure conditions affecting the conditions within the outer chamber 15. The seal 38 sealing the heater element feedthrough 37 comprises, for example, a cover plate or a liner outside the outer chamber 15, for sealing the heater element 30 entrance. In an embodiment, the seal 38 is a vacuum flange sealing the heater element 30 entrance into the outer chamber 15. In an embodiment, in its operational position the at least one heater element 30 is positioned entirely inside the intermediate space 40, formed between the reaction chamber 11 and the outer chamber 15. In such embodiment, the heater element 30 is inserted to its operational position in the intermediate space 40 through the heater element feedthrough 37 and the heater element 30 is coupled with the heater element feedthrough 37 indirectly, for example, via a wire. Such indirect coupling of the heater element 30 reduces the risk of overheating of the feedthrough 37 and of the structures in contact with the feedthrough 37. In such embodiments, other means to support the heater element(s) 30 and/or the heat distributor(s) 20 in the correct operational position can be arranged inside the outer chamber 15 instead, or in addition to the support given by the heater element feedthrough 37.

In certain embodiments, in its operational position, the at least one heater element 30 further extends through the at least one substantially horizontal reflection plate 35, 36, located in the intermediate space 40 below or above the reaction chamber 11. The at least one substantially horizontal reflection plate 35, 36 is provided with a suitable opening(s), for the at least one heater element 30 to penetrate it removably and/or reversibly. In certain embodiments, the apparatus 10 comprises more than one overlaid substantially horizontal reflection plate 35, 36 layered below or above the reaction chamber 11, in which case the at least one heater element 30 extends through these overlaid substantially horizontal reflection plates 35, 36. In certain other embodiments, the at least one heater element 30 extends through the at least one substantially vertical reflection plate 35′, 36′, located in the intermediate space 40 beside the reaction chamber 11. The at least one substantially vertical reflection plate 35′, 36′ is provided with a suitable opening(s), for the at least one heater element 30 to penetrate it removably and/or reversibly. In certain embodiments, the apparatus 10 comprises more than one overlaid substantially vertical reflection plate 35′, 36′ layered beside the reaction chamber 11, in which case the at least one heater element 30 extends through these overlaid substantially vertical reflection plates 35′, 36′.

In its operational position inside the intermediate space 40, the at least one heater element 30 is coupled with at least one heat distributor 20. In certain embodiments, each individual heat distributor 20 inside the intermediate space 40, is coupled with at least one heater element 30. In certain embodiments, each individual heat distributor 20 inside the intermediate space 40, is coupled with more than one heater element 30. In certain embodiments, one individual heat distributor 20 inside the intermediate space 40, is coupled with at least one other heat distributor 20 coupled with at least one heater element 30. The at least one heat distributor 20 takes up the heat emitted by the at least one heater element 30 and further distributes it evenly all around the periphery of the reaction chamber 11, thereby providing the necessary heat for the surface reactions taking place inside the reaction chamber 11. Preferably, the material of the heat distributor(s) 20 has a good thermal conductivity. For instance, the material of the heat distributor(s) 20 is aluminum. In certain embodiments the heat distributor(s) can be at least partly made of, or comprise, copper, brass, titanium, steel, ceramic, nitride or carbide.

In certain embodiments, the surface of the heat distributor(s) 20 facing the reaction chamber 11 has an increased total surface area, when compared to the surface of the heat distributor(s) 20 facing the outer chamber 15. In certain embodiments, the total surface area of the heat distributor(s) 20 facing the reaction chamber 11 is 1,5, preferably 2, more preferably 4 times larger than the surface area of the heat distributor(s) 20 facing the outer chamber 15. The surface of the heat distributor(s) 20 facing the reaction chamber 11 has a high electromagnetic thermal emissivity. In certain embodiments, the surface of the heat distributor(s) 20 facing the reaction chamber 11 is coated with a material that has a high electromagnetic thermal emissivity. For example, the surface of the heat distributor(s) 20 facing the reaction chamber 11 has a coating comprising nitride (such as silicon nitride) or a carbide (such as tungsten carbide). In certain embodiments, the thickness of the coating on the heat distributor 20 surface facing the reaction chamber 11 is optimized for maximal thermal emission. The plane or surface of the heat distributor(s) 20 facing the outer chamber 15, on the other hand, is smooth, even, polished, or unwrinkled, and the material of the of the heat distributor(s) 20 facing the outer chamber 15 has a low thermal emissivity. In certain embodiments, the surface of the heat distributor(s) 20 facing the outer chamber 15 can be coated with a material that has a low thermal emissivity. In certain embodiments, the thickness of the coating on the heat distributor(s) 20 surface facing the outer chamber 15 is optimized for minimal thermal emission. For example, the material of the surface of the heat distributor(s) 20 facing the outer chamber 15, or the material of the coating on the surface of the heat distributor(s) 20 facing the outer chamber 15 is copper, gold, silver, brass, nickel or steel, for example.

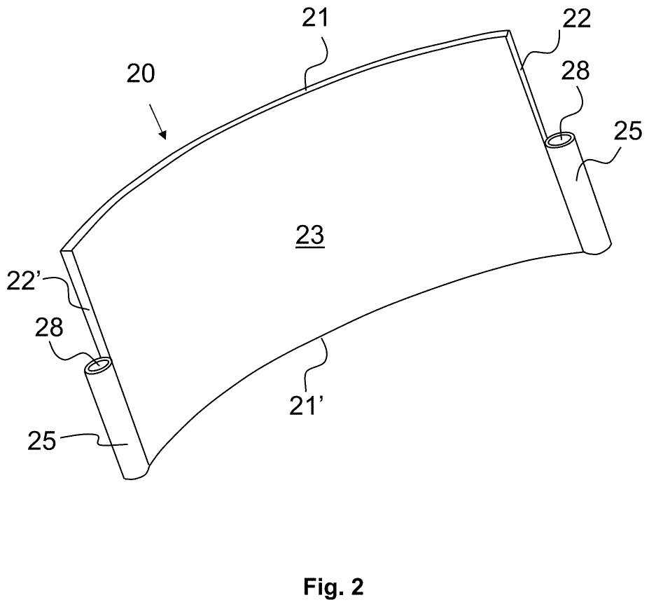

In certain embodiments, the shape of the at least one heat distributor 20 is a curved, bent or arched, and it is shaped as a flat panel-shaped object, preferably adapted to position itself at least partly around the reaction chamber 11. The at least one heat distributor 20 comprises some sort of an opening or a hole 28 in its structure, for the heater element 30 to be at least partly positioned inside the heat distributor 20. The opening or hole 28 can be, for example, formed in a bushing or a duct. For example, the heater element 30, can be placed inside a bushing or a duct which is a short linker cylinder 25 at a narrow edge 21,21′,22,22′ of the heat distributor 20, as presented in an example embodiment of FIG. 2. Any two adjacent heat distributors 20, have the short linker cylinders 25 at different positions in their respective narrow edges 21,21′,22,22′. Therefore, when the adjacent heat distributors 20 are positioned next to each other, the respective short linker cylinders 25 have overlapping positions adjacent to each other. This structure allows the heater element 30 to be inserted in a position, wherein it is inside both two short linker cylinders 25 of the adjacent two heat distributors 20.

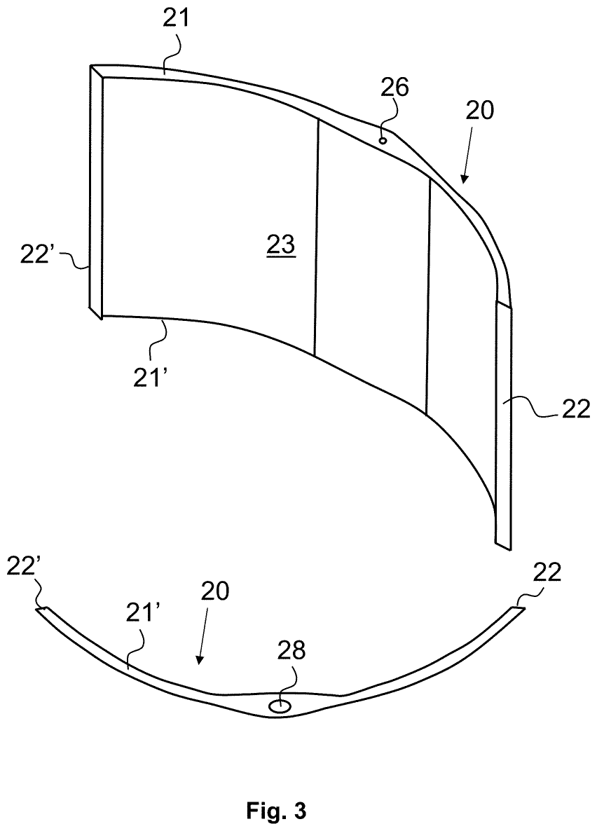

Other types of solutions for the heater element 30 entry inside the heat distributor(s) 20 can just as well be utilized. Alternatively, as shown in FIG. 3, the heater element 30 is configured to be placed inside an opening or a hole 28 which extends completely or partly through the body of the heat distributor 20 as a duct. The opening or hole is configured to pierce one of the narrow edges 21,21′,22,22′ of the heat distributor 20 and to extend completely or partly through the entire heat distributor 20 as a duct. In certain embodiments, wherein the opening or hole 28 extends only partly through the heat distributor 20, an air opening 26 is provided on the opposite narrow edge from the opening or hole 28. The air opening 26 merges into a cavity of the opening or hole 28, to arrange vacuum conditions during the operation of the apparatus. In certain embodiments, wherein the air opening 26 merges into the cavity of the opening or hole 28, the air opening 26 is configured to have a smaller diameter than the hole 28, preventing the heater element 30 from penetrating through the heat distributor 20. In certain embodiments, a lower narrow edge 21,21′,22,22′ of the heat distributor 20 comprises at least one hole 28 for the heater element 30 entry, the weight of the heat distributor 20 thereby at least partly resting on the at least one heater element 30 inserted at least partly inside the heat distributor 20. In an alternative embodiment, one of the narrow edges 21,21′,22,22′ of the heat distributor 20 comprises at least one opening or hole 28 for the heater element 30 entry through the entire heat distributor 20 in the plane of the narrow edge 21,21′,22,22′. In such embodiments, the support of the weight of the at least one heat distributor 20 is organized in other ways.

In certain other embodiments, the at least one heat distributor 20 comprises at least one fastening (not shown), for attaching the heater element(s) 30 to the heat distributor 20, without the need for the heater element(s) 30 to be necessarily placed inside the heat distributor 20. The structure of the heat distributor 20 is thereby configured to couple the at least one heater element 30 with the heat distributor 20. For example, the at least one heat distributor 20 may have support structures, such as rings or loops (not shown) in its narrow edge(s) 21,21′,22,22′ or on its panel-like surface 23, for coupling the at least one heater element 30.

In certain embodiments, one heat distributor 20 comprises plurality of openings or holes 28 for coupling plurality of heater elements 30 to the one heat distributor 20. In certain embodiments, one heater element 30 can be coupled with one heat distributor 20, or it can be coupled with two heat distributors 20 simultaneously, depending on the design of the heat distributor(s) 20.

In a preferred embodiment, the apparatus comprises more than one heater element 30, these heater elements 30 being distributed evenly around the surrounding periphery of the reaction chamber 11, to provide heat to the reaction chamber uniformly. For example, the apparatus comprises two heater elements 30, preferably three heater elements 30, or more preferably four heater elements 30. In some embodiments, the apparatus comprises more than four heater elements 30.

In certain embodiments, the apparatus 10 comprises a plurality of heat distributors 20, which are coupled to each other and to the at least one heater element 30, and which heat distributors 20 surround most or all of the periphery of the reaction chamber 11 in the intermediate space 40. In certain embodiments, the apparatus 10 comprises a plurality of heat distributors 20, which are coupled to each other and to the at least one heater element 30, and which heat distributors 20 cover the top and/or the bottom of the reaction chamber 11 in the intermediate space 40. In certain embodiments, the apparatus 10 comprises a plurality of heat distributors 20, which are coupled to each other and to the at least one heater element 30, and which heat distributors 20 surround most or all of the periphery and the top and/or the bottom of the reaction chamber 11 in the intermediate space 40. In certain embodiments, the heat distributor 20, is connected to a second heat distributor 20 via the heater element 30, the said heater element 30 holding the assembly together. In certain embodiments, the apparatus 10 comprises a plurality of heat distributors 20, which are connected to each other through at least one heater element 30, and which heat distributors 20 surround most or all of the periphery of the reaction chamber 11 in the intermediate space 40. Each individual heat distributor 20 can be shaped, for example, as a quarter hollow cylinder, a quarter circle hollow cylinder or a bow, whereupon the periphery of the reaction chamber 11 is surrounded by four individual heat distributors 20. In certain alternative embodiments, different amounts or numbers of heat distributors 20 of other or different shapes, surround most or all of the periphery of the reaction chamber 11. Yet in another embodiment, the apparatus 10 comprises only one heat distributor 20, which is shaped as a hollow cylinder which cylinder can be circular in shape, and which surrounds the periphery of the reaction chamber 11 in the intermediate space 40. In certain embodiments, most or all of the periphery of the reaction chamber 11 in the intermediate space 40 is surrounded by the heat distributor(s) 20. In certain other embodiments, most of the reaction chamber 11 is enclosed or encased by the heat distributor(s) 20 in the intermediate space 40. Assembly and disassembly of the heat distributor(s) 20 to and from the apparatus 10, is possible through the openable lid assembly 17, without removing the heater element(s) 30 first.

In certain embodiments, the apparatus comprises a sheath element 45 between the heater element 30 and the at least one heat distributor 20, as shown in FIGS. 4 and 5. The sheath element 45 distributes heat arriving from the heater element 30 into the heat distributor(s) 20 coupled to it and protects the heater element 30 by covering it. In certain embodiments, the sheath element 45 provides support for the at least one heat distributor 20. In certain embodiments, the heat distributor 20, is connected to a second heat distributor 20 via the sheath element 45, the said sheath element 45 participating in holding the assembly together. In certain embodiments, the sheath element 45 protects the heater element 30 from oxidation. In certain embodiments, the sheath element 45 prevents the at least one heater element 30 from being exposed to the conditions prevailing in the intermediate space 40. Preferably, the material of the sheath element 45 has a good thermal conductivity. For instance, the material of the sheath element 45 is aluminum. The sheath element 45 has an elongated sleeve-like shape, its inner cavity being configured to fit tightly against the outer surface of the heater element 30. The heater element 30 can be removably and/or reversibly placed at least partly inside the inner cavity of the sheath element 45, through an opening at a first distal tip of the elongated sheath element 45. In certain embodiments, a second distal tip of the sheath element 45 is closed, forming a closed cap on top of the tip of the heater element 30, as shown in the example embodiment of the FIG. 4. In certain other embodiments, the second distal tip of the sheath element 45 may also be open to the inner cavity of the sheath element 45, as shown in the example embodiment of the FIG. 5. In certain embodiments, the entire heater element 30 is covered by the sheath element 45 within the intermediate space 40. In certain embodiments, each heater element 30 is covered by the sheath element 45 inside the intermediate space 40 beyond the point where it penetrates the heater element feedthrough 37. In some embodiments, only a distal tip of the heater element 30 is exposed to the conditions prevailing in the intermediate space 40. The sheath element 45 is sealed tightly together with the seal 38 between the heater element feedthrough 37 and the heater element 30, as shown in FIG. 5. The sheath element 45 may be coupled with the seal 38 inside the heater element feedthrough 37 or at the entrance to the intermediate space 40. In certain embodiments, the seal 38 is a flange, such as a vacuum flange. The seal 38 may comprise an o-ring, which is sealing the connection between the sheath element 45 and the seal 38. In certain other embodiments, the entire sheath element 45 is located within a space delimited by at least one layer of substantially vertical reflection plates 35′, 36′ above and below the reaction chamber 11. In such embodiments, part of the heater element 30 is exposed to the conditions prevailing in the intermediate space 40. In certain embodiments, the entire sheath element 45 is located within a space delimited by at least one layer of substantially horizontal reflection plates 35, 36 above and below the reaction chamber 11.

In an embodiment, the heater element 30, such as a cartridge heater, can be vacuum tightly inserted at least partly inside the sheath element 45, which provides electric insulation inside its inner cavity. In certain embodiments, the electric contacts of the heater element 30 are provided outside the intermediate space 40 (not shown), the said electric contacts (cables) thereby not being exposed to vacuum. In certain embodiments, the sheath element 45 covering at least partly the heater element 30, can be braced tightly on the seal 38, such as the vacuum flange, thereby preventing the exposure of the electric contacts of the heater element 30 to vacuum. In certain embodiments, the part of the heater element 30 coupled with the at least one heat distributor 20 is configured to reach a higher temperature than the part of the heater element 30 outside the outer chamber 15, thereby making the part of the heater element 30 outside the outer chamber 15 pleasant to touch to enable insertion and removal of the at least one heater element 30 by an operator.

In certain embodiments, the sheath element 45 comprises a surface structure, configured to support and to fix the position of the at least one heat distributor 20. The said position may be fixed vertically, horizontally, or both. More specifically, the outer surface of the sheath element 45 comprises a bulge or a rise, on which the weight of the at least one heat distributor 20 can be supported against, as shown in the FIG. 4. For example, the sheath element 45 comprises a bulge or a rise at the outer edge surface of its distal tip, through which the heater element 30 is removably and/or reversibly placed at least partly inside the inner cavity of the sheath element 45. Therefore, in an embodiment, when the heater element 30 is fully inserted in its operational position substantially vertically inside the sheath element 45 and the at least one heat distributor 20, the lower rim of the at least one heat distributor 20 is supported on top of the bulge of the sheath element 45. Alternatively, the said bulge or a rise of the sheath element 45 can be positioned elsewhere along the elongated shaft of the the sheath element 45. In certain other embodiments, the support for the at least one heat distributor 20 is provided through alternative structural solutions of the said parts of sheath element 45 and/or at least one heat distributor 20. For example, according to certain embodiments wherein the heater element 30 is inserted substantially vertically inside the intermediate space 40 through the lid structure 17, other assembly solutions are utilized for the heater elements 30, sheath elements 45 and the heat distributors 20.

Without limiting the scope and interpretation of the patent claims, certain technical effects of one or more of the example embodiments disclosed herein are listed in the following. A technical effect is easily removable and exchangeable heater element. For example, in case the heater element needs to be replaced to a new one due to oxidation in the heater element surface, the old heater element can be easily removed and replaced to a new one. A further technical effect is easily removable and exchangeable heat distributor(s). The heat distributor(s) can be removed simply through the openable lid of the apparatus. A further technical effect is that the surface of the heat distributor facing the reaction chamber is configured to emit thermal energy differently, when compared to the surface of the heat distributor facing the heat reflectors and the outer chamber. A further technical effect is avoiding a contact between the heater element(s) with conditions prevailing in the intermediate space, thereby avoiding oxidation in the heater element surface. A further technical effect is avoiding a contact between the electrical components of the heater element(s) with vacuum conditions prevailing in the intermediate space. A further technical effect is connecting the heat distributor(s) indirectly or directly to the heater element(s), enable distribution of thermal energy evenly in the reaction chamber periphery and to the reaction chamber.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means without deviating from the characteristics of the invention. Furthermore, some of the features of the above-disclosed embodiments of this invention may be used to advantage without the corresponding use of other features. As such, the foregoing description should be considered as merely illustrative of the principles of the present invention, and not in limitation thereof. Hence, the scope of the invention is only restricted by the appended patent claims.

1. A substrate processing apparatus, comprising:
a reaction chamber;
an outer chamber at least partly surrounding the reaction chamber, wherein an intermediate space is formed between the reaction chamber and the outer chamber;
at least one heater element;
at least one heat distributor in the intermediate space; and
at least one heater element feedthrough in the outer chamber allowing at least a part of the at least one heater element to pass through into the intermediate space and to couple with the at least one heat distributor.

2. The apparatus of claim 1, wherein the at least one heater element is configured to be removably coupled with the at least one heat distributor.

3. The apparatus of claim 1, wherein the at least one heater element is an elongated rod-shaped element.

4. The apparatus of claim 1, wherein the at least one heater element is configured to be removably placed, at least partly, in the intermediate space between the outer chamber and the reaction chamber, through the heater element feedthrough in the outer chamber.

5. The apparatus of claim 1, comprising a plurality of heat distributors, the plurality of heat distributors surrounding at least partly the periphery of the reaction chamber.

6. The apparatus of claim 1, wherein the at least one heat distributor is configured to heat the reaction chamber to a uniform temperature.

7. The apparatus of claim 1, wherein the at least one heat distributor is a panel-like element and/or a curved structure.

8. The apparatus of claim 1, comprising a sheath element between the at least one heater element and the at least one heat distributor, to protect the at least one heater element.

9. The apparatus of claim 8, wherein the sheath element comprises a surface structure which supports the at least one heat distributor.

10. The apparatus of claim 8, wherein the at least one heater element is configured to be removably placed, at least partly, inside the sheath element.

11. The apparatus of claim 1, wherein the at least one heater element, in its operational position, is placed at least partly inside each of
the intermediate space;
the sheath element;
the at least one heat distributor; and
the heater element feedthrough.

12. A method, comprising:
providing an outer chamber at least partly surrounding a reaction chamber of a substrate processing apparatus, wherein an intermediate space is formed between the reaction chamber and the outer chamber;
passing at least a part of at least one heater element into the intermediate space through a heater element feedthrough in the outer chamber; and
coupling at least one heat distributor in the intermediate space with the at least one heater element.

13. The method of claim 12, comprising:
removably coupling the at least one heater element with the at least one heat distributor.

14. The method of claim 12, comprising:
removably placing the at least one heater element at least partly in the intermediate space between the outer chamber and the reaction chamber, through the heater element feedthrough in the outer chamber.

15. The method of claim 12, comprising:
heating the reaction chamber to a uniform temperature with heat distributed by the at least one heat distributor.
